(19) United States
(12) Patent Application Publication
(10) Pub. No.: US 2025/0347723 A1
(43) Pub. Date: Nov. 13, 2025

(54) DISTRIBUTED DYNAMIC TEMPERATURE COMPENSATION FOR SHUNTS

(71) Applicant: Infineon Technologies AG, Neubiberg (DE)

(72) Inventors: Michael Asam, Inchenhofen-Sainbach (DE); Peter Reimer, Neubiberg (DE)

(21) Appl. No.: 18/658,572

(22) Filed: May 8, 2024

(51) Int. Cl. G01R 19/32; G01R 1/20

(52) U.S. Cl. CPC G01R 19/32; G01R 1/203

(57) ABSTRACT

An example device includes an electrical component configured to carry an electrical current, and an electrical circuit configured to measure the electrical current through the electrical component. The electrical circuit includes a temperature sensor configured to measure a temperature signal indicative of a temperature of the electrical component and a voltage sensor configured to measure a voltage signal indicative of a voltage across the electrical component that is proportional to the electrical current. The device also includes a micro-controller configured to control operation of the electrical circuit. The micro-controller includes a filter configured to estimate a temperature change of the electrical component for a first set of time constants based on the voltage signal. The set of time constants include time constants having values that are greater than or equal to 10 milliseconds (ms).

### TECHNICAL FIELD

The disclosure relates to measurement of temperature at a thermal junction to compensate for the impact in temperature on electrical current measurements.

### BACKGROUND

Very high currents in the range of several hundred amperes may flow in the electrical system of modern automobiles. The currents may be controlled by electronic switches, such as transistors. Accurate measurement of the currents in such systems may be useful to determine the utilization of the supply network and to protect the battery, cables and consumers from overload.

### SUMMARY

In general, the disclosure describes techniques for measuring a temperature of an electrical component, such as a shunt, a wire, a transistor, a switch, or the like, of an electrical device. Circuitry may control electrical components that carry high electrical current, e.g., 100 amperes (A) or more. The relatively high currents may cause the electrical component to heat, e.g., via self-heating, which may cause the electrical properties of the electrical component to change as a function of temperature, e.g., the electrical resistance and/or impedance of the electrical component may be temperature-dependent. Accurate current measurements by the circuitry may depend on accurate estimation and/or modeling of the electrical properties of the electrical components as a function of temperature, and the electrical device may include one or more temperature sensors for measuring the temperature of circuit components. For example, the device may include a thermal sensor configured to measure a junction temperature of a power switch, such as a power transistor. However, the temperature sensor may be spaced a distance from the portion of the electrical component that self-heats, e.g., an active area (e.g., junction) of the power transistor, and there may be material between the temperature sensor and the active area of the electrical component, e.g., the temperature sensor may be connected to, but not in direct contact, with the junction of the power transistor. As such, there may be both a time-delay between measurement of the temperature of the electrical component and an off-set between the actual temperature of the component and the temperature value measured by the temperature sensor due to the distance and intervening material.

Temperature measurement time-delays and off-sets may be corrected and/or compensated by modeling the thermal system and the electrical component (or components) being measured. For example, a temperature sensor and electrical component may be modeled as being thermally coupled by a network of thermal resistances and thermal capacitances, e.g., representing the thermal properties of the materials of the temperature sensor and electrical component, and representing the thermal properties of the material between (and thermally connecting or coupling) the temperature sensor and electrical component. Such a thermal network model may be an analog of a signal filter, and may be implemented similarly to a signal filter.

For example, the thermal network model, e.g., thermal filter (also referred to hereinafter is “filter”) may receive one or more input signals, e.g., a voltage drop across the electrical component that is proportional to a current through the electrical component, and a temperature value measured and/or sensed by the temperature sensor, and the filter may output a correction to the value of the measured temperature based on the input signals (voltage and measured temperature) and filter parameters (e.g., the parameters of the thermal model of the electrical component). Implementation of such a filter may require relatively complicated calculations, such that implementation of the filter integrated with the control circuitry, e.g., within a gate-driver circuitry for a power transistor operating as a power switch, may require significant area on the chip in which the control circuitry is implemented. Out-sourcing such calculations to a processor, such as a micro-controller, may result in delay, e.g., due to the need to communicate via a communication bus connecting the micro-controller and the control circuitry, such that fast load current changes through the electrical component (e.g., which may result in fast heating of the electrical component) may be missed.

As disclosed herein, techniques for determining the temperature of an electrical component include separating a complicated thermal model into multiple parts, e.g. two or more parts, and implementing the multiple parts as different filters with different filter parameters. For example, a first filter may model and/or estimate the temperature of the electrical component for a first set of thermal time constants, e.g., relatively slower thermal time constants (e.g., greater than about 10 milliseconds (ms)) to estimate temperature changes of the electrical component occurring over relatively longer periods of time, e.g., from longer-term load current changes. A second filter may model and/or estimate the temperature of the electrical component for a second set of thermal time constants, e.g., relatively faster thermal time constants (e.g., less than or equal to about 10 milliseconds (ms)) to estimate temperature changes of the electrical component occurring over relatively shorter periods of time, e.g., from shorter-term load current changes. The second filter may have a simpler structure, e.g., the second filter may be of low order (e.g., a 1st order filter) and can therefore be implemented in a very small area and integrated with the circuitry, e.g., on the same chip. The first filter may be outsourced to the micro-controller because of the slow time constants and the associated slow changes at the output. In some examples, the techniques and devices disclosed herein may include only the first filter outsourced to the micro-controller, e.g., the circuitry may not include the first filter and may be corrected by the thermal model for only slow load current changes, for applications (such as shorts) that do not require accurate measurements of fast-changing currents.

In one example, this disclosure describes a device including: an electrical component configured to carry an electrical current; an electrical circuit configured to measure the electrical current through the electrical component, the electrical circuit includes a temperature sensor configured to measure a temperature signal indicative of a temperature of the electrical component; and a voltage sensor configured to measure a voltage signal indicative of a voltage across the electrical component that is proportional to the electrical current; and a micro-controller configured to control operation of the electrical circuit, the micro-controller includes a filter configured to estimate a temperature change of the electrical component for a first set of time constants based on the voltage signal, wherein the set of time constants include time constants having values that are greater than or equal to 10 milliseconds (ms).

In another example, this disclosure describes a system including: a micro-controller circuit configured to control operation of a gate-driver circuit, the micro-controller circuit comprising a first digital filter; and the gate-driver circuit comprising a second filter, wherein the gate-driver circuit is configured to control operation of a power switch, and wherein the first digital filter is configured to model temperature compensation of the power switch for a first set of time constants, and wherein the second digital filter is configured to model temperature compensation of the switch for a second set of time constants, and wherein each time constant in the first set of time constants is less than or equal to time constants in the second set of time constants.

In another example, this disclosure describes a method including: controlling operation of a gate-driver circuit, by a micro-controller circuit, wherein the micro-controller circuit comprises a first digital filter, wherein the first digital filter is configured to model a first temperature compensation of a power switch for a first set of time constants; measure, by the gate-driver circuit, a voltage across the power switch, wherein gate-driver circuit comprises a second filter configured to model a second temperature compensation of the power switch for a second set of time constants; and modeling, by the micro-controller executing the first filter, the first temperature compensation of the power switch for the first set of time constants, wherein each time constant in the second set of time constants is less than or equal to time constants in the first set of time constants.

Details of these and other examples are set forth in the accompanying drawings and the description below. Other features, objects, and advantages will be apparent from the description and drawings, and from the claims.

### BRIEF DESCRIPTION OF DRAWINGS

FIG. 1 is a block diagram of an example electrical device.

FIG. 2A is schematic block diagram illustrating an example thermal coupling between a temperature sensor and an electrical component.

FIG. 2B is a plot of both an example actual temperature of the electrical component of FIG. 2A and a measured temperature of the electrical component by the temperature sensor of FIG. 2A.

FIG. 3A is a block diagram illustrating a simple thermal model of the electrical component of FIG. 2A mounted on a circuit board.

FIG. 3B is a schematic diagram illustrating a Cauer thermal equivalent circuit of the simple thermal model of FIG. 3A.

FIG. 3C is a schematic diagram illustrating a Foster thermal equivalent circuit of the simple thermal model of FIG. 3A.

FIG. 4 is a block diagram of another example electrical device.

FIG. 5 is a block diagram of another example electrical device.

FIG. 6 is a block diagram of another example electrical device.

FIG. 7 is a flow diagram illustrating an example method of temperature compensation of temperature of an electrical component.

### DETAILED DESCRIPTION

In general, the disclosure describes techniques and devices for measuring a temperature of an electrical component. In various applications, electrical currents need to be measured. For example, in vehicle power networks of modern vehicles, high currents of 100 amperes (A) or more may be flowing, and the currents may be switched using power MOSFETs (metal oxide semiconductor field effect transistors). A precise measurement of the current may be required to determine a degree of utilization of the power network and to protect components like a battery, power lines and loads against overcurrents. For example, electrical fuses may be used where an electrical connection is interrupted using, for example, a MOSFET switch in case of an overcurrent.

Electrical currents may be measured using a shunt resistor. The current to be measured flows through the shunt resistor, and a voltage across the shunt resistor is measured to determine the current. However, the current flowing through the shunt resistor may heat the shunt resistor. To allow precise measurements, in conventional solutions, special shunt resistors may be used which have a substantially constant resistance over a temperature range of interest, e.g., high temperature shunts that can dissipate electrical power without changing its electrical characteristics or properties. Such temperature-constant shunt resistors may be relatively costly, may break down over time, and may occupy area on a printed circuit board.

The electrical characteristics or properties of other non-temperature-constant components, such as the resistance or impedance of a simple copper clip, may change as a function of the temperature of the electrical component as it heats due to the electrical current. A change in resistance/impedance of the electrical component also changes the voltage drop across the copper clip. For example, for a copper shunt, a temperature difference of about 5 degrees kelvin (K) (and equivalently 5 degrees Celsius (C)), the resistance of the copper shunt may change by about 2%. For a temperature range between −40° C. and 125° C., which may be a temperature range for electrical components for automotive applications, the overall variation in resistance depending on the temperature may be almost a factor of two from the lowest to the highest temperature.

The temperature-dependence of the electrical properties, parameters, and/or characteristics of electrical components may be estimated (e.g., calculated based on a thermal model) based on temperature measurements of the electrical components, and then used to correct measurements of the current using such electrical components.

However, accurate measurement of the temperature of electrical components, or electrically active portions of the electrical components (e.g., such as a junction of a MOSFET), may be difficult because it may not be possible or feasible to directly contact and/or measure the electrically portion of the electrical component. For example, a temperature sensor may be positioned proximate to an electrical component such as a MOSFET, but cannot be placed in direct thermal contact with the junction of the MOSFET and also, as a practical matter, may be positioned at least a distance away from the MOSFET. The measurement values of the temperature measurements sensed by the temperature sensor may then be delayed in time and also off-set in value due to thermal material being between the electrical component and the sensor.

For example, circuitry may determine current, e.g., for a MOSFET, according to I_{Load}=VDS/RDSₒₙ, where I_{Load} is the current flowing through a drain-source channel of the MOSFET, VDS is the voltage across the drain-source channel, and RDSₒₙ is the resistance of the drain-source channel. RDSₒₙ may change as a temperature of a junction of the MOSFET, Tj, changes, e.g., caused by self-heating, as the I_{Load} changes. In some examples, RDSₒₙ may change rapidly with rapid I_{Load} changes. Circuitry for measuring the junction temperature, Tj, and circuitry for measuring VDS, may be implemented in the switch controller, e.g., the gate-driver circuitry for the switch. For example, the gate-driver circuitry may include a temperature sensor substantially near the MOSFET configured to measure a temperature of the MOSFET, however, the temperature sensor is external to the MOSFET and is a distance from the MOSFET, resulting in delayed and off-set temperature measurements.

The delayed and off-set temperature measurements may be compensated for by modeling the thermal system (e.g., the MOSFET, the sensor, and the materials coupling the sensor and the MOSFET) as a network of thermal resistances and thermal capacitances. Such a thermal network model may be implemented similarly to a signal filter, and may receive one or more signals, e.g., a measured voltage drop across the electrical component and a temperature sensed by the temperature sensor, and output a correction to the measured temperature (or may output corrected temperature values). However, the temperature compensation using the thermal model/filter may be computationally complicated and/or heavy such that implementing the filter within the gate-driver circuitry may require significant area on the chip. Additionally, out-sourcing implementation of the filter to a micro-controller may be too slow because of the need to communicate data via a communication bus communicatively coupling the micro-controller and the gate-driver circuitry of the MOSFET.

In accordance with the techniques and devices disclosed herein, a method and device for determining a temperature of an electrical component includes separating a filter (e.g., a thermal model) into multiple filters configured to estimate the temperature of an electrical component for different sets of time constants. For example, a device may include device may include a micro-controller and/or micro-controller circuit configured to control operation of gate-driver circuitry configured to control operation of a power switch. The micro-controller (or micro-controller circuit) may include a first filter configured to estimate the temperature of the power switch for a first set of time constants, e.g., greater than about 10 milliseconds, and the estimated temperature may be used to compensate for changing electrical properties due to temperature changes on the order of the first set of time constants. The device may also include the gate-driver circuitry, and the gate-driver circuitry may include a second filter configured to estimate the temperature of the power switch for a second set of time constants, e.g., less than or equal to about ten milliseconds. The estimated temperature from the second filter, with or without the estimate temperature by the first filter, may be used to compensate for changing electrical properties due to temperature changes on the order of the second set of time constants, e.g., for correction for rapid I_{Load} changes. In some examples, the temperature estimate from the first filter of the micro-controller may be added to the temperature estimate of the second filter, e.g., by the gate-driver circuitry, and in some examples, the first filter may be configured to dynamically modify filter coefficients for the second filter. For example, the first filter may output both a temperature estimate and updated filter coefficients for the second filter, e.g., coefficients for correcting longer time-scale temperature changes.

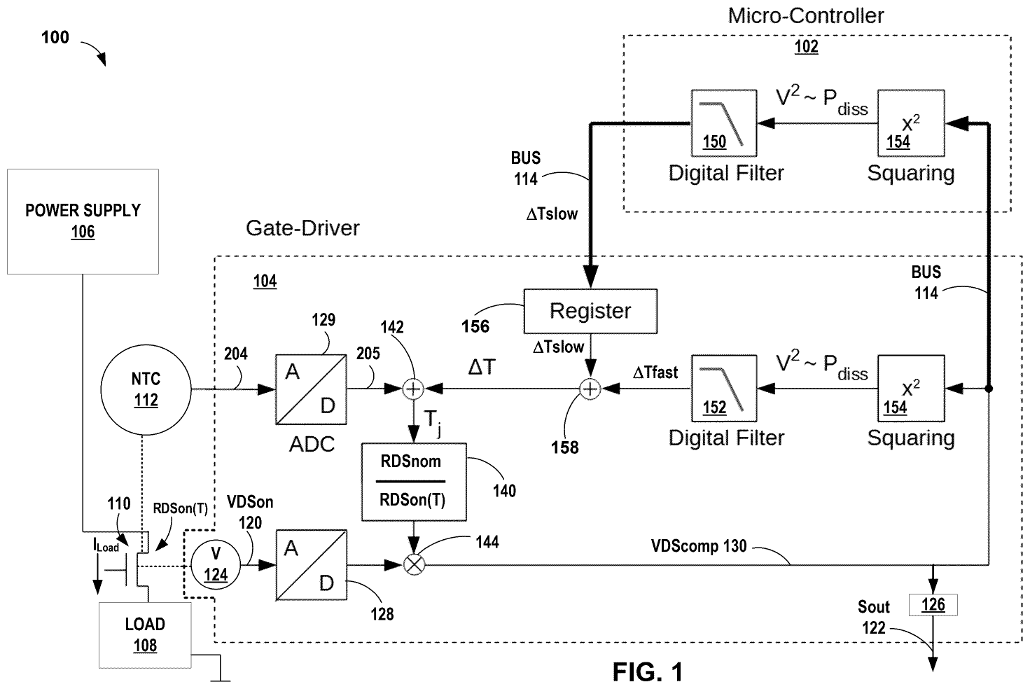

FIG. 1 is a block diagram of an example electrical device 100. Device 100 includes micro-controller 102, gate-driver circuitry 104, power supply 106, current load 108, electrical component 110, temperature sensor 112, and communication bus 114. Micro-controller 102 may be configured to control the operation of gate-driver circuitry 104, and to communicate with gate-driver circuitry 104 via communication bus 114. Gate-driver circuitry 104 may be configured to measure a current through, or a voltage across, electrical component 110. In some example, gate-driver circuitry may be configured to control the operation of electrical component 110, e.g., where electrical component 110 comprises a power switch, such as a MOSFET. Gate-driver circuitry 104 may be configured to output a signal Sout 122 indicative of an electrical current through electrical component 110.

In the example shown, power supply 106 is electrical connected to current load 108 via electrical component 110, and is configured to provide the voltage for current load 108 to draw electrical current through electrical component 110. Although described herein as a power switch having a drain-source resistance RDSₒₙ, electrical component 110 may be any electrical component with a well-defined relationship between the load current I_{Load} and a voltage drop (e.g., a drain-source voltage drove VDS 120 in the case of a power switch) across electrical component 110.

In the example shown, electrical component 110, has a temperature dependent resistance, e.g., RDSon(T) for a MOSFET power switch. For example, in case of a shunt resistor made of copper or a power switch such as a MOSFET, the resistance changes substantially linearly as a function of temperature. Generally, for resistive elements made of a metal, the temperature dependence of the resistance may be substantially linear over temperature ranges of interest.

In the example shown, gate-driver circuitry 104 includes voltmeter 124 configured to measure the voltage across electrical component 110 and provide the voltage measurement VDSon 120 to analog-to-digital (A.D) converter 128. A/D converter 128 may be configured to provide the voltage measurement across electrical component 110 in digitized form. Gate-driver circuitry 104 may generate the output signal Sout 122 indicative of the current I_{Load} based on the voltage measurement VDSon 120. This output signal Sout 122 may be corrected for the temperature dependence of RDSon(T) of electrical component 110.

In the example shown, gate-driver circuitry 104 may be configured to receive a temperature measurement 204 from temperature sensor 112. Temperature sensor 112 may be thermally coupled to electrical component 110 such that temperature changes of electrical component 110 are measured by temperature sensor 112. In some examples, the temperature measurements of temperature sensor 12 may allow for “static,” “or steady-state” temperature correction, e.g., to compensate for a particular temperature of electrical component 110 that is substantially constant over a substantially long (e.g., seconds or more) period of time. Gate-driver circuitry 104 may then correct the output signal Sout based on the temperature measurements of temperature sensor 112. In the examples shown in FIGS. 1-6, temperature sensor 112 comprises a negative temperature coefficient (NTC)-based temperature sensor, however, temperature sensor 112 may be a diode, a sensor sensing a thermal voltage on a metal junction, a proportional to absolute temperature (PTAT) current sensor, or any suitable temperature sensor.

In some examples, the temperature measured by temperature sensor 112 follows the temperature of electrical component 110 in a delayed manner, such that, for example, a temperature rise of electrical component 110 is reflected in the measured temperature only with a time delay. This time delay may be caused by the thermal coupling between electrical component 110 and temperature sensor 112, via a circuit board or other elements, and/or by a thermal inertia of the temperature sensor 112 itself. Additionally, the temperature measurement by the temperature sensor 112 may not be the actual temperature of electrical component 110, e.g., there may be an off-set between the measured and actual temperature due to the thermal capacitances and resistances of the materials coupling temperature sensor 112 and electrical component 110.

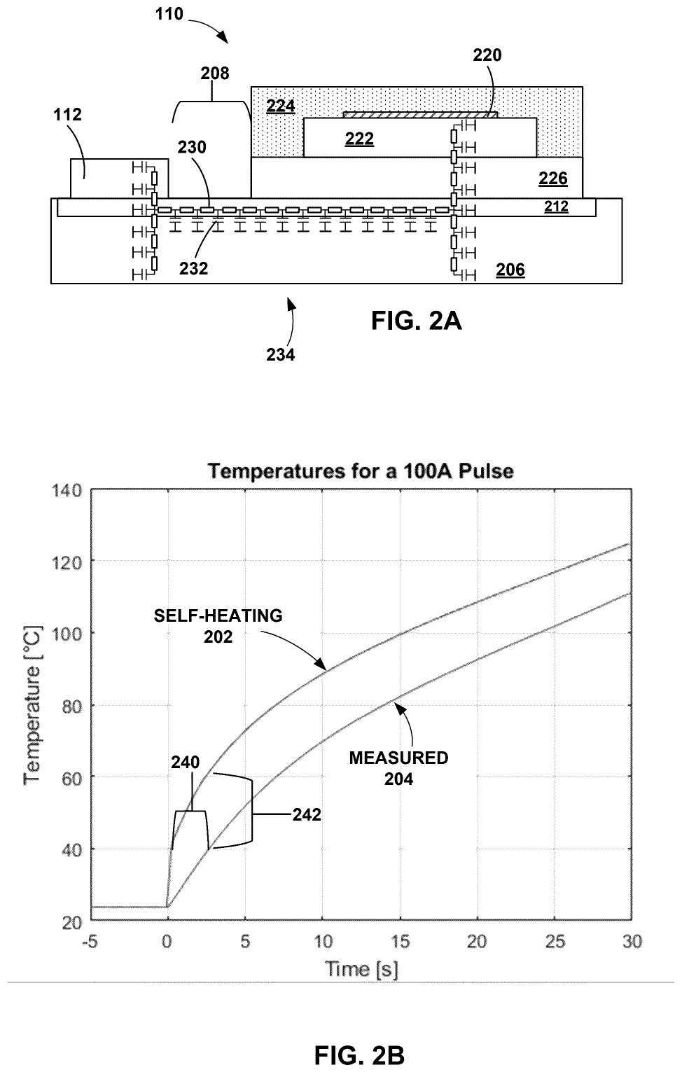

FIGS. 2A and 2B illustrate an example of temperature measurement delay and temperature measurement off-set. FIG. 2A is schematic block diagram illustrating an example thermal coupling between temperature sensor 112 and electrical component 110, and FIG. 2B is a plot of both an example actual temperature 202 of electrical component 110 and a measured temperature 204 by temperature sensor 112 thermally coupled to electrical component 110 as illustrated in FIG. 2A. In the examples shown, temperature sensor 112 comprises a negative temperature coefficient (NTC)-based temperature sensor thermally coupled to (e.g., bonded to) a copper trace 212 of a printed circuit board (PCB) 206. Electrical component 110 is also thermally coupled to (e.g., bonded to) copper trace 212 of PCB 206 a distance 208 from temperature sensor 112. In the example shown, electrical component 110 comprises a MOSFET comprising a junction 220 on silicon 222 and encapsulated in a mold 224. The silicon is disposed on a copper conducting plane 226, which is coupled to, e.g., bonded to, copper trace 212. The resistance RDSon(T) of electrical component 110 depends on the temperature of junction 220. In the example shown in FIG. 2A, the thermal coupling between temperature sensor 112 and junction 220 may be modeled as a plurality of thermal resistances 230 and thermal capacitances 232 arranged in a thermal equivalent circuit 234. In the example shown, thermally equivalent circuit 234 may be a Cauer network, e.g., a thermal analog of a linear electrical circuit (e.g., an RC circuit, or a plurality of RC circuits connected in series) modeled according to a Cauer network synthesis. The observed time-delay 240 and temperature measurement off-set 242, illustrated in FIG. 2B, may be modeled (e.g., calculated via choosing the correct model parameters/characteristics) via thermal equivalent circuit 234.

Typical time constants of such a delay may be of the order of 3 to 10 seconds. For example, distance 208 between temperature sensor 112 and electrical component 110 may be several millimeters or centimeters, e.g., to 10 centimeters (cm), and heat takes time to flow from the junction 220 to temperature sensor 112, and additionally the mass of the temperature sensor 112 (even if small) takes some time to be heated. The time-delay may correspond to “low-pass” behavior of temperature sensor 112, e.g., high-frequency temperature changes may be filtered out, or blocked, by the response of the temperature sensor 112 and electrical component 110 thermal system (e.g., modeled as thermal network 234), and low-frequency temperature changes may be passed. For example, temperature sensor 112 may exhibit corner frequencies (e.g., low-pass filter behavior) f=1/(2πτ) Hz, where τ is the time constant, which may be from 3 to 10 seconds. These values are only examples and may vary depending on the type of temperature sensor and the thermal coupling between junction 220 and temperature sensor 112.

Returning to FIG. 1, in cases of short circuits or other overcurrent events, the current through electrical component 110 I_{Load} may rise rapidly, which may lead to a rapid increase in temperature of electrical component 110. Such rapid changes of the temperature of electrical component 110 are reflected in the temperature measured by temperature sensor 112 only with a delay, as described above.

In some examples, gate-driver circuitry 104 may be configured to estimate an indication of a temperature change of electrical component 110 based on the voltage VDSon 120 across electrical component 110 (e.g., which may be a value that reflects a temperature change) and corrects the output signal Sout 122 based on both the temperature measurement 204 by temperature sensor 112 and VDSon 120 (e.g., the indication of the rapid temperature changes). In some examples, temperature correction of VDSon 120 by gate-driver circuitry 104 based on both temperature measurements 204 (slow variations) and VDSon 120 measurement (the indication of rapid temperature changes) may enable more precise determination of Sout 122 (determination of the current through electrical component 110), e.g., in cases of a rapid increase of the temperature of electrical component 110 due to rapidly rising currents. Compensation and/or correction of the temperature of such comparatively rapid temperature increases using the indication of the temperature change is also referred to as “dynamic” correction herein.

For example, the measured VDSon 120 may indicate the correct, measured voltage across electrical component 110 to be used to determine Sout 122, and may also indicate rapid temperature changes, while determination of Sout 122 based on an uncorrected VDSon 120 as described herein may result in inaccurate values for Sout 122 due to RDSon(T) changing as a function of temperature. Temperature sensor 112 may provide some correction for the changing RDSon(T), but not for rapid changes. VDSon 120 may be used adjust the measured temperature for rapid temperature changes in order to provide a correction to VDSon 120, e.g., VDScomp 130, in a feedback loop as shown in order to determine the correct, or more accurate, Sout 122, as described further below.

In the example shown, VDSon 120 is corrected (in digitized form) by correction factor 140. Correction factor 140 may be determined based on a ratio between the resistance of electrical component 110, e.g., RDSon(T) at the corrected temperature of electrical component 110, to the nominal resistance RDSnom of electrical component 110, e.g., which may be RDSon(T) at a particular temperature, such as room temperature. The corrected temperature may be an estimate of the actual temperature of electrical component 110, as described further below. In some examples, correction factor 140 may be calculated for a simple linear electrical component 110, e.g., with a substantially linear dependance of the resistance RDSon(T), and in other examples, correction factor 140 may based on a calibration curve of electrical component 110, e.g., with a substantially non-linear dependance of the resistance RDSon(T). In the example shown, once the temperature of electrical component 110 is correct and/or compensated for, correction factor 140 may be determined and gate-driver circuitry 104 is configured to determine VDScomp 130 as a multiplication 144 of the digitized VDSon 120 by correction factor 140. In some example, gate-driver circuitry 104 may output VDScomp 130 as the corrected output signal, Sout 122. In the example shown, gate-driver circuitry 104 may be configured to control a sub-circuit 126 to determine Sout 122 based on VDScomp 130, e.g., sub-circuit 126 may determine a corrected I_{Load} based on the corrected VDScomp 130 and RDSon(T) with the corrected temperature.

As described above, temperature sensor 112 may be configured to provide temperature measurement T values of electrical component 110, e.g., in digitized form 205, for determination of correction factor 140. Temperature sensor 112 may effectively provide the baseline temperature value T, which may include slow, e.g., low-pass filtered, temperature changes (e.g., on the order of seconds). VDSon, as measured by voltmeter 124, may be used to provide correction ΔT of the temperature T of electrical component 110 for fast temperature changes, e.g., VDSon 120 may provide low-pass filtered, or band-pass filtered, temperature changes ΔT for temperature T. In the example shown, device 100 may include low-pass filters 150 and 152, each configured to provide low-pass filtered, or band-pass filtered, temperature correction values (e.g., when combined, ΔT) for temperature T for different sets of time constants. For example, a low-pass (or band-pass) filter may be split into low-pass filters 150 and 152 in order to reduce the size and/or chip area used by gate-driver circuitry 104 for filtering by out-sourcing at least a portion of the low-pass (or band-pass) filter to micro-controller 102. Although referred to herein as low-pass filters 150, 152, filters 150, 152 may also be band-pass filters. In some examples, low-pass filter 150 may be configured to provide temperature correction values based on VDSon 120 for relatively slow temperature changes, e.g., time constants greater than about 10 ms, and low-pass filter 152 may be configured to provide temperature correction values based on VDSon 120 for relatively fast temperature changes, e.g., time constants less than or equal to about 10 ms. Low-pass filter 150, with time constants greater than 10 ms, may then be a “slow filter” 150, e.g., relative to low-pass filter 152, but is still not a “low-pass” filter such as temperature sensor 112, e.g., which has time constants on the order of seconds. For convenience, low-pass filter 150 may be referred to herein as “slow filter 150” and low-pass filter 152 may be referred to herein as “fast filter 152.”

In some examples, gate-driver circuitry 104 may be configured to correct the temperature of electrical component 110 by combining the temperature correction values of temperature sensor 110, slow filter 150 temperature correction values, and fast filter temperature correction values, e.g., at 142 in the example shown. Slow filter 150 and fast filter 152 may each be different portions of a thermal model of electrical component 110.

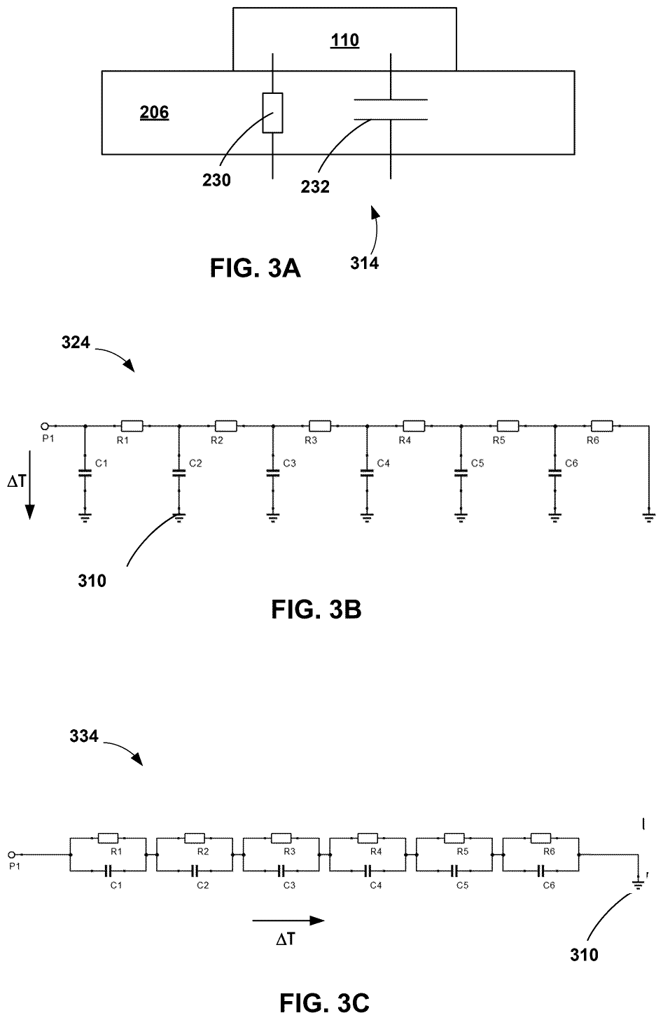

FIGS. 3A-3C are schematic illustrations of thermal models of electrical component 110. FIG. 3A illustrates a simple thermal model 314 of electrical component 110 mounted on a circuit board 206, e.g. a printed circuit board, FIG. 3B illustrates a schematic diagram of a Cauer thermal equivalent circuit 324 of the arrangement of FIG. 3A, and FIG. 3C illustrates a schematic diagram of a Foster thermal equivalent circuit 334 of the arrangement of FIG. 3A. The circuits of FIGS. 3B and 3C are not an electrical circuits, but a person skilled in the art will understand that thermal circuits may be represented in a manner similar to electrical circuits, and the behavior of thermal circuits may be modeled by corresponding electrical circuits.

Circuit board 206 and other components, such as leads on circuit board 206, have a thermal resistance 230 with a resistance value Rth and a thermal capacitance 232 with a capacitance value Cth. Thermal capacitance 232 may represent the thermal capacity of circuit board 206 and other components like leads, and thermal resistance 230 may represent the inverse of the thermal conductivity of circuit board 206 and those other components. Together, thermal capacitance 232 and thermal resistance 230 determine how fast heat can be thermally conducted away from electrical component 110.

Thermal circuit 324 of FIG. 3B may include a plurality of thermal capacitances, e.g., C1-C6, and a plurality of thermal resistances, e.g., R1-R6, each having particular thermal capacitance Cth and thermal resistance Rth values. Thermal circuit 324 may receive the power P dissipated in electrical component 110 via the current I_{Load} passing through electrical component 110 as an input value. This dissipated power P is proportional to the square of the electric current I_{Load} flowing through electrical component 110 and is proportional to the square of the voltage across electrical component 110, e.g., (VDSon 120)². In the example shown, thermal model 324 may be a Cauer network thermal model 324 Temperature ground 310 in FIGS. 3B and 3C represents the environment temperature, which may then be the temperature measured by a temperature sensor like temperature sensor 112 of FIG. 1. AT is the difference between the temperature of the electrical component 110 and temperature ground 310, e.g., an analog of a voltage drop in an electrical circuit.

The Cauer network thermal model 324 may be mathematically transformed into a Foster network thermal 334 of FIG. 3C, e.g., with different values of thermal capacitances C1-C6 thermal resistances R1-R6. Foster network thermal model 334 comprises an addition or series connection of thermal RC filters. For example, Foster network thermal 334 may be formed by summing the outputs of the plurality of thermal RC filters, and Foster network thermal 334 may be divided into multiple filters, e.g., slow filter 150 and fast filter 152 of FIG. 1, based on their corresponding time constants. The parameters and/or filter coefficients of slow and fast filters 150, 152 are the thermal capacitance values C1-C6 thermal resistance values R1-R6, and may be determined via calibration. Although Foster network thermal 334 is shown as a series connection of six RC filters, Foster network thermal 334 may include fewer or more RC filters.

In some examples, the Foster network thermal 334 may be divided such that fast filter 152 has a relatively simpler structure, e.g., as compared to the full Foster network thermal 334 and/or the Cauer network thermal model 324, and may be of lower order, e.g., first order. Fast filter 152 may then be implemented in a very small area, e.g., a small chip area within gate-driver circuitry 104. Slow filter 150 may be out-sourced to micro-controller 102 to save chip area.

Returning to FIG. 1, the feedback loop of device 100 is described. Gate-driver circuitry 104 may include analog-to-digital (A.D) converter 129 configured to convert the temperature measurement 204 to digitized temperature measurement 205. Gate-driver circuitry 104 may determine correction factor 140 using digitized temperature measurement 205. Gate-driver circuitry 104 may then apply (e.g., multiply) the correction factor 140 to the digitized VDSon 120 to determine VDScomp 130. Gate-driver circuitry 104 may be configured to then square VDScomp 130 such that VDScomp 130 is proportional to power P dissipated by electrical component 110 at squaring operation 154, and filter the squared VDScomp 130 via fast filter 152 according to a set of time constants, e.g., to estimate temperature change ΔTfast according to time constants less than or equal to about 10 ms. In some examples, gate-driver circuitry 104 is configured to estimate ΔTfast based on a difference between VDScomp 130 at the current time and a previous VDScomp 130 from a previous time. For example, if VDScomp 130 does not change over a period of time (e.g., less than 10 ms), the power dissipated in electrical component 110 may not have changed over the time period and the temperature of electrical component 110 may be the same over that time period. In other examples, gate-driver circuitry 104 is configured to estimate ΔTfast based on only VDScomp 130 at the current time, e.g., based on the most recent measurement of VDSon 120.

In the example shown, gate-driver circuitry 104 may be configured to provide VDScomp 130 to micro-controller 102, e.g., via communication bus 114. Communication bus 114 may include a serial peripheral interface (SPI), input-output (I/O) lines, or any suitable means for communicating data and/or signals between gate-driver circuitry 104 and micro-controller 102. In the example shown, micro-controller 102 is configure to square VDScomp 130 such that VDScomp 130 is proportional to power P dissipated by electrical component 110 at squaring operation 154, and filter the squared VDScomp 130 via slow filter 150 according to a set of time constants different than the set of time constant of fast filter 152, e.g., to estimate temperature change ΔTslow according to time constants greater than about 10 ms. Micro-controller 102 may be configured to then provide updates to the estimated temperature change, e.g., ΔTslow, to gate-driver circuitry 104 via communication bus 114. Gate-which may hold ΔTslow in a register 156 in order to synchronize timing of adding ΔTslow to the most recent ΔTfast estimated by gate-driver circuitry 104 executing fast filter 152. Gate-driver circuitry 104 may be configure to determine ΔT by adding ΔTslow and ΔTfast at addition operation 158, and add ΔT to the digitized temperature T from measurement of the temperature by temperature sensor 112 at addition operation 142 to determine an estimated temperature of electrical component 110 at the most recent time, e.g., the estimate of the actual junction temperature Tj of MOSFET 110. Gate-driver circuitry 104 may then recalculate correction factor 140 based on the most recent estimated temperature and execute the loop again for a subsequent measurement of VDSon 120 and/or temperature 204.

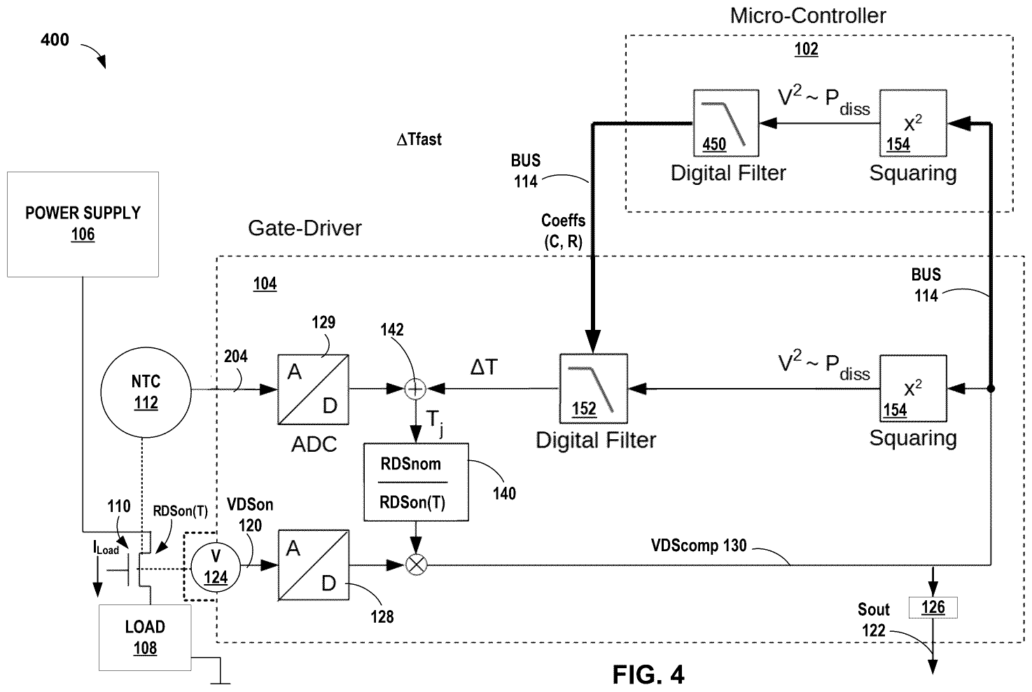

FIG. 4 is a block diagram of another example electrical device 400. Device 400 may be substantially similar to device 100 described above, except for the differences described herein. Device 100 includes micro-controller 102, gate-driver circuitry 104, power supply 106, current load 108, electrical component 110, temperature sensor 112, and communication bus 114. Device 400 may be configured to execute the temperature compensation loop in a different way. For example, micro-controller 102 may include slow filter 450 rather than slow filter 150. Slow filter 450 may be substantially the same as slow filter 150, except that slow filter 450 may be configured to output filter coefficients, or updates to filter coefficients, to gate-driver circuitry 104 via communication bus 114 for fast filter 152. For example, micro-controller 102 may execute slow filter 450 and output both ΔTslow and one or more coefficients (C, R) (e.g., one or more of C1-C6, R1-R6 of thermal model 334) for fast filter 152, or just output the one or more coefficients (C, R) to gate-driver circuit 104. Gate-driver circuit may be configured to then update the filter coefficients for fast filter 152, and filter squared VDScomp 130 via fast filter 152 to determine ΔT.

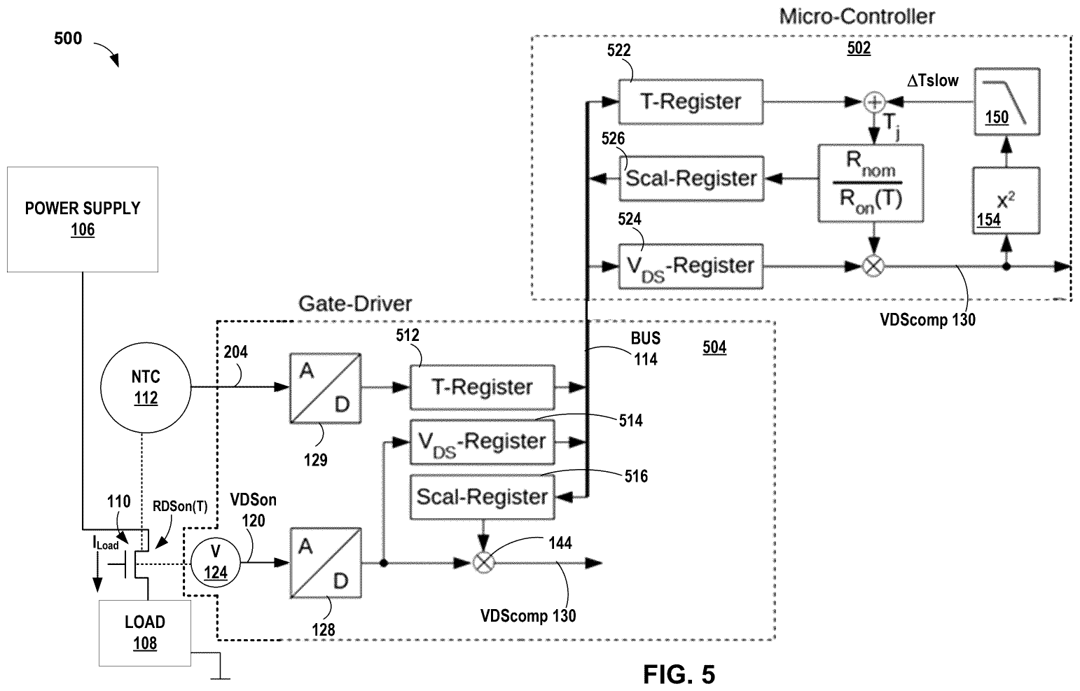

FIG. 5 is a block diagram of another example electrical device 500. Device 500 may be substantially similar to device 100 described above, except for the differences described herein. Device 500 includes micro-controller 502, gate-driver circuitry 504, power supply 106, current load 108, electrical component 110, temperature sensor 112, and communication bus 114. Device 500 may include on fast filter 104 and may be configured to compensate only for relatively slow temperature changes for a set of time constants, e.g., greater than about 10 ms. For example, fast current load changes and the associated fast temperature changes of electrical component 110 may not be expected, and device 500 may be configured to further reduce the chip area for gate-driver circuitry 504, and to simplify gate-driver circuitry, by out-sourcing all of the filtering/temperature compensation calculation to micro-controller 502, including determination and/or calculation of correction factor 140, temperature multiplication calculations block 142, and voltage squaring calculations block 154. In the example shown, gate-driver circuitry 504 is configured to receive measured temperature 204 and measured voltage VDSon 120 and digitize the measured temperature 204 via A/D converter 129 and digitize the measured voltage VDSon 120 via A/D converter 128, as described with reference to FIG. 1. Gate-circuitry 504 may then be configured to output the digitized temperature and VDSon 120 to micro-controller 502 via temperature register 512, voltage register 514 and communication bus 114. Gate-driver circuitry 504 may be configured to receive a correction factor, Scal, via Scal register 516. Micro-controller 502 may be configured to receive the digitized measured temperature and the digitized measured VDSon 120 via communication bus 114 and temperature register 522 and voltage register 524, determine correction factor Scal, and output correction factor Scal via Scal register 526 and communication bus 114 to gate-driver circuitry 504. Registers 512, 514, 516, 522, 524, and 526 may be configured to store values, e.g., for synchronizing data input/output operations between gate-driver circuitry 504 and micro-controller 502.

In the example shown, micro-controller 502 is configured to determine correction factor Scal, and both micro-controller 502 and gate-driver circuitry 504 are configured to determine an updated (e.g., most recent) compensated voltage, VSDcomp 130, based on the most recent measured VDSon 120 and Scal, e.g., via multiplication 144. For example, micro-controller 502 may be configured to receive VSDcomp 130 via register 524, square VSDcomp 130 at squaring operation 154 to determine the power P dissipated in electrical component 110, estimate the temperature change ΔTslow for the set of relatively slow time constants, e.g., greater than about 10 ms, and add the estimated ΔTslow to the received temperature mea122surement from register 522 to determine the most recent temperature estimate of electrical component 110 (e.g., Tj in the case of a MOSFET electrical component 110). Micro-controller 502 may then determine the correction factor Scal via correction factor calculation block 140, as described above, and the loop may repeat for a subsequent receipt of VDScomp 130 by register 524 or a subsequent receipt if a measured temperature by register 522, e.g., a subsequent temperature measurement by temperature sensor 112 or a subsequent voltage measurement of VDSon 120 by voltmeter 124.

Micro-controller 502 may be configured to also output the most recent correction factor Scal to register 526 for communication to gate-driver circuitry 504, and gate-driver circuitry 504 may receive correction factor Scal via register 516 and calculate the updated compensated voltage VDScomp 130, e.g., via multiplication 144. One or both of micro-controller 504 and gate-driver circuitry 504 may include a sub-circuit 126 (not shown in FIG. 5) and be configured to determine output signal Sout 122 (e.g., the corrected/compensated current through electrical component 110) as described above with reference to FIG. 1. In some examples, gate-driver circuitry 504 may not need to calculate an updated compensated voltage VDScomp 130, such as for overcurrents. For example, in the case of an overcurrent, gate-driver circuitry 504 may output VDSon 120 rather than VDScomp 130, and a threshold of a comparator may be adjusted (e.g., by micro-controller 502, or gate-driver circuitry 504, or other processing circuitry, to determine an overcurrent based on VDSon 120.

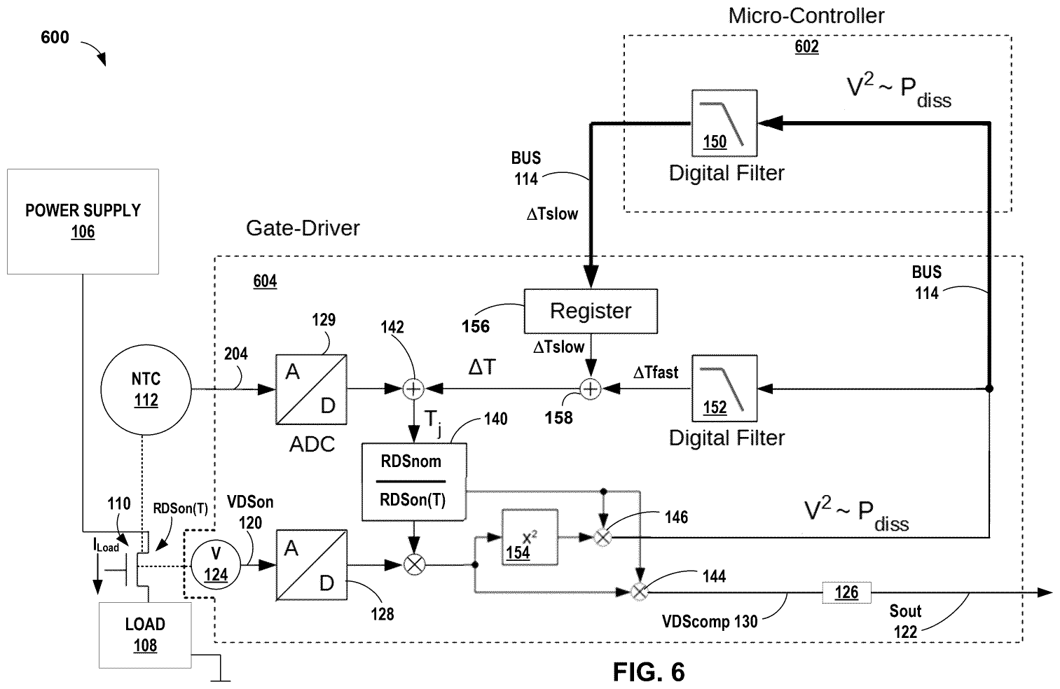

FIG. 6 is a block diagram of another example electrical device 600. Device 500 may be substantially similar to device 100 described above, except for the differences described herein. Device 600 includes micro-controller 102, gate-driver circuitry 104, power supply 106, current load 108, electrical component 110, temperature sensor 112, and communication bus 114. Device 600 may be configured to execute the temperature compensation loop in a different way, e.g., from devices 100 and 400 described above. For example, with reference to FIG. 1, the power dissipation in electrical component 110 is only calculated approximately at squaring blocks 154. As the temperature of electrical component 110 increases, RDSon may increases linearly and squared voltage VDScomp 130 may increase quadratically, and thus the total power dissipated P (e.g., the fraction (VDScomp 130)²/RDSon) may increase linearly. In order to calculate the dissipated power P with improved accuracy, the correction factor Rnom/Ron(T) (e.g., Scal) may be multiplied by squaring block 154, as shown in FIG. 6. Gate-driver circuitry 604 may then include an additional multiplier block 146.

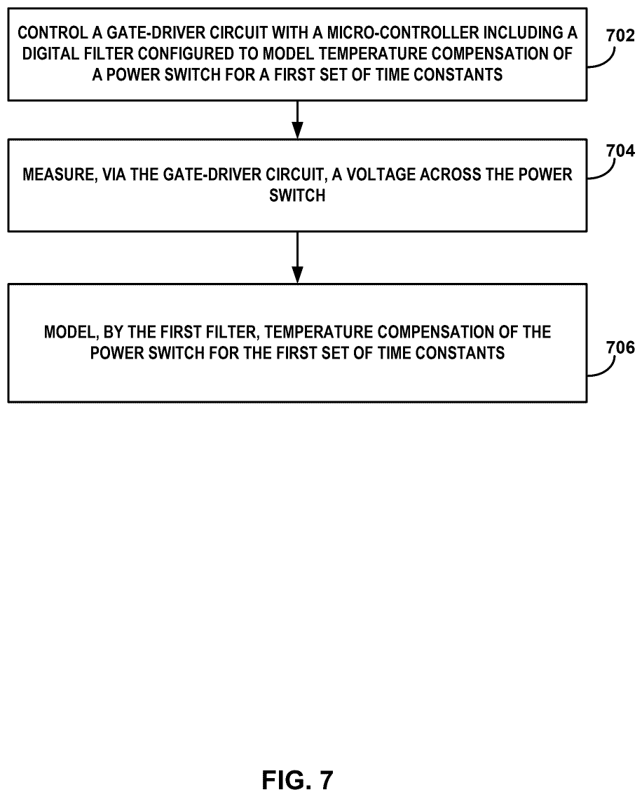

FIG. 7 is a flow diagram illustrating an example method of temperature compensation of a measured temperature of an electrical component 110. Although the example method of FIG. 7 is described with respect to devices 100, 400, 500, and 600 of FIGS. 1-6, the example technique of FIG. 7 may be performed using any device including a micro-controller and an electrical measurement circuit, e.g., a gate-driver circuit.

Micro-controller 102 may control operation of gate-driver circuitry 104 (702). For example, micro-controller may send and receive communication signals and/or data via communication bus 114 to control gate-driver circuitry 104 to operate power switch 110. Gate-driver circuitry 104 may measure a voltage VDSon 120 across power switch 110 (704). For example, voltmeter 124 may measure VDSon 120 across power switch 110.

Micro-controller 102 may model a first temperature compensation ΔTslow for a first set of time constants (706). For example, micro-controller 102 may filter a squared VDScomp 130 via slow filter 150 to determine ΔTslow for a first set of time constants that are slower, e.g., greater than or equal to, the set of time constants of fast filter 152 of gate-driver circuitry 104. Filter 150 may be a digital filter implemented in software executable by micro-controller 102, and filter 152 may be implemented in hardware within gate-driver circuitry 104.

The techniques described in this disclosure may be implemented, at least in part, in hardware, software, firmware or any combination thereof. For example, various aspects of the described techniques may be implemented within one or more processors or processing circuitry, including one or more micro-controllers (e.g., micro-controllers 102, 502, and/or 602), microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various operations and functions described in this disclosure. In addition, any of the described units, circuits or components may be implemented together or separately as discrete but interoperable logic devices. Depiction of different features as circuits or units is intended to highlight different functional aspects and does not necessarily imply that such circuits or units must be realized by separate hardware or software components. Rather, functionality associated with one or more circuits or units may be performed by separate hardware or software components or integrated within common or separate hardware or software components.

The techniques described in this disclosure may also be embodied or encoded in a computer-readable medium, such as a computer-readable storage medium, containing instructions that may be described as non-transitory media. Instructions embedded or encoded in a computer-readable storage medium may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

Various aspects of the techniques may enable the following examples.

Example 1: A device includes: an electrical component configured to carry an electrical current; an electrical circuit configured to measure the electrical current through the electrical component, the electrical circuit includes a temperature sensor configured to measure a temperature signal indicative of a temperature of the electrical component; and a voltage sensor configured to measure a voltage signal indicative of a voltage across the electrical component that is proportional to the electrical current; and a micro-controller configured to control operation of the electrical circuit, the micro-controller includes a filter configured to estimate a temperature change of the electrical component for a first set of time constants based on the voltage signal, wherein the set of time constants include time constants having values that are greater than or equal to 10 milliseconds (ms).

Example 2: The device of example 1, further comprising a communication bus configured to communicatively couple the electrical circuit and the micro-controller.

Example 3: The device of example 1 or example 2, wherein the electrical component comprises a shunt.

Example 4: The device of example 3, wherein the shunt comprises a power switch comprising at least one of a metal oxide semiconductor field effect transistor, an insulated-gate bipolar transistor, a gallium nitride transistor, or a bipolar junction transistor.

Example 5: The device of example 4, wherein the electrical circuit comprises a gate-driver circuit configured to control operation of the power switch.

Example 6: The device of any one of examples 1-5, wherein the filter is a first filter, wherein the set of time constants is a first set of time constants, wherein the temperature change is a first temperature change, wherein the electrical circuit further comprises: a second filter configured to estimate a second temperature change of the electrical component for a second set of time constants based on the voltage signal, wherein the time constants of the second set of time constants are less than or equal to the time constants of the first set of time constants.

Example 7: The device of example 6, wherein the first filter operates independently from the second filter, wherein the second filter comprises a digital filter.

Example 8: The device of example 6 or example 7, wherein the second set time constants of the second filter are configured to compensate for short-term load changes carried by the power switch.

Example 9: The device of any one of examples 6-8, wherein the first digital filter is configured to output the first estimated temperature change to the electrical circuit via a communication bus, and wherein the electrical circuit is configured to add the first estimated temperature change to the second estimated temperature change from the second filter.

Example 10: The device of any one of examples 6-9, wherein the first filter is configured to dynamically modify filter coefficients for the second filter via a communication bus.

Example 11: The device of any one of examples 1-10, wherein the first filter is implemented in software, and wherein the second digital filter is implemented in hardware.

Example 12: A system includes a micro-controller circuit configured to control operation of a gate-driver circuit, the micro-controller circuit comprising a first digital filter; and the gate-driver circuit comprising a second filter, wherein the gate-driver circuit is configured to control operation of a power switch, and wherein the first digital filter is configured to model temperature compensation of the power switch for a first set of time constants, and wherein the second digital filter is configured to model temperature compensation of the switch for a second set of time constants, and wherein each time constant in the first set of time constants is less than or equal to time constants in the second set of time constants.

Example 13: The system of example 12, further comprising a power supply configured to apply power to a load via the power switch.

Example 14: The system of example 12 or example 13, wherein the second set time constants of the second digital filter are configured to compensate for short-term load changes carried by the power switch.

Example 15: The system of any one of examples 12-14, further comprising a temperature sensing circuit, wherein the gate-driver circuit is configured to receive a first signal output from the temperature sensing circuit indicating a temperature of the system, wherein the gate-driver circuit is further configured to receive a second signal output from the power switch indicating a drain-source voltage (VDS) of the power switch, and wherein the gate-driver circuitry comprises a temperature compensation loop that operates based on the first signal output and the second signal output.

Example 16: The system of example 15, further comprising a communication bus configured to communicate at least between the micro-controller and the gate-driver.

Example 17: The system of example 16, wherein the first digital filter is configured to output updates to the gate-driver via the communication bus, and wherein the gate-driver adds the updates from the first digital filter to the temperature compensation loop.

Example 18: The system of example 16 or example 17, wherein the first digital filter is configured to dynamically modify filter coefficients for the second digital filter via the communication bus.

Example 19: A method includes controlling operation of a gate-driver circuit, by a micro-controller circuit, wherein the micro-controller circuit comprises a first digital filter, wherein the first digital filter is configured to model a first temperature compensation of a power switch for a first set of time constants; measure, by the gate-driver circuit, a voltage across the power switch, wherein gate-driver circuit comprises a second filter configured to model a second temperature compensation of the power switch for a second set of time constants; and modeling, by the micro-controller executing the first filter, the first temperature compensation of the power switch for the first set of time constants, wherein each time constant in the second set of time constants is less than or equal to time constants in the first set of time constants.

Example 20: The method of example 19, wherein the second digital filter is implemented in software, and wherein the first digital filter is implemented in hardware.

Various examples have been described. These and other examples are within the scope of the following claims.

What is claimed is:

1. A device comprising:
an electrical component configured to carry an electrical current;
an electrical circuit configured to measure the electrical current through the electrical component, the electrical circuit comprising:
a temperature sensor configured to measure a temperature signal indicative of a temperature of the electrical component; and
a voltage sensor configured to measure a voltage signal indicative of a voltage across the electrical component that is proportional to the electrical current; and
a micro-controller configured to control operation of the electrical circuit, the micro-controller comprising:
a filter configured to estimate a temperature change of the electrical component for a first set of time constants based on the voltage signal,
wherein the set of time constants include time constants having values that are greater than or equal to 10 milliseconds (ms).

2. The device of claim 1, further comprising a communication bus configured to communicatively couple the electrical circuit and the micro-controller.

3. The device of claim 1, wherein the electrical component comprises a shunt.

4. The device of claim 3, wherein the shunt comprises a power switch comprising at least one of a metal oxide semiconductor field effect transistor, an insulated-gate bipolar transistor, a gallium nitride transistor, or a bipolar junction transistor.

5. The device of claim 4, wherein the electrical circuit comprises a gate-driver circuit configured to control operation of the power switch.

6. The device of claim 1, wherein the filter is a first filter, wherein the set of time constants is a first set of time constants, wherein the temperature change is a first temperature change, wherein the electrical circuit further comprises:
a second filter configured to estimate a second temperature change of the electrical component for a second set of time constants based on the voltage signal, wherein the time constants of the second set of time constants are less than or equal to the time constants of the first set of time constants.

7. The device of claim 6, wherein the first filter operates independently from the second filter, wherein the second filter comprises a digital filter.

8. The device of claim 6, wherein the second set time constants of the second filter are configured to compensate for short-term load changes carried by the power switch.

9. The device of claim 6, wherein the first digital filter is configured to output the first estimated temperature change to the electrical circuit via a communication bus, and wherein the electrical circuit is configured to add the first estimated temperature change to the second estimated temperature change from the second filter.

10. The device of claim 6, wherein the first filter is configured to dynamically modify filter coefficients for the second filter via a communication bus.

11. The device of claim 1, wherein the first filter is implemented in software, and wherein the second digital filter is implemented in hardware.

12. A system comprising:
a micro-controller circuit configured to control operation of a gate-driver circuit, the micro-controller circuit comprising a first digital filter; and
the gate-driver circuit comprising a second filter,
wherein the gate-driver circuit is configured to control operation of a power switch, and
wherein the first digital filter is configured to model temperature compensation of the power switch for a first set of time constants, and
wherein the second digital filter is configured to model temperature compensation of the switch for a second set of time constants, and
wherein each time constant in the first set of time constants is less than or equal to time constants in the second set of time constants.

13. The system of claim 12, further comprising a power supply configured to apply power to a load via the power switch.

14. The system of claim 12, wherein the second set time constants of the second digital filter are configured to compensate for short-term load changes carried by the power switch.

15. The system of claim 12, further comprising a temperature sensing circuit,
wherein the gate-driver circuit is configured to receive a first signal output from the temperature sensing circuit indicating a temperature of the system,
wherein the gate-driver circuit is further configured to receive a second signal output from the power switch indicating a drain-source voltage (VDS) of the power switch, and
wherein the gate-driver circuitry comprises a temperature compensation loop that operates based on the first signal output and the second signal output.

16. The system of claim 15, further comprising a communication bus configured to communicate at least between the micro-controller and the gate-driver.

17. The system of claim 16,
wherein the first digital filter is configured to output updates to the gate-driver via the communication bus, and
wherein the gate-driver adds the updates from the first digital filter to the temperature compensation loop.

18. The system of claim 16, wherein the first digital filter is configured to dynamically modify filter coefficients for the second digital filter via the communication bus.

19. A method comprising:
controlling operation of a gate-driver circuit, by a micro-controller circuit, wherein the micro-controller circuit comprises a first digital filter, wherein the first digital filter is configured to model a first temperature compensation of a power switch for a first set of time constants;
measure, by the gate-driver circuit, a voltage across the power switch, wherein gate-driver circuit comprises a second filter configured to model a second temperature compensation of the power switch for a second set of time constants; and
modeling, by the micro-controller executing the first filter, the first temperature compensation of the power switch for the first set of time constants,
wherein each time constant in the second set of time constants is less than or equal to time constants in the first set of time constants.

20. The method of claim 19,
wherein the second digital filter is implemented in software, and
wherein the first digital filter is implemented in hardware.
